(19) United States
(12) Patent Application Publication
(10) Pub. No.: US 2025/0357243 A1
(43) Pub. Date: Nov. 20, 2025

(54) SEMICONDUCTOR DEVICE PACKAGE WITH DUAL-SIDED COOLING

(71) Applicant: Tesla, Inc., Austin (TX)

(72) Inventors: William Thomas Chi, Fremont, CA (US); Sesha Sai Srikant Sarma Gandikota, San Jose, CA (US); Hiep Nguyen, San Francisco, CA (US)

(21) Appl. No.: 18/871,333

(22) PCT Filed: Jun. 13, 2023
(86) PCT No.: PCT/US2023/025189

§ 371 Date: Dec. 3, 2024

Related U.S. Application Data
(60) Provisional application No. 63/366,451, filed on Jun. 15, 2022.

(51) Int. Cl. H01L 23/367; H01L 23/00; H01L 23/373

(52) U.S. Cl. CPC H01L 23/3675; H01L 23/3736; H01L 24/40; H01L 2224/40247

(57) ABSTRACT

A device may include a semiconductor die. A device may include a bottom heat spreader and a top heat spreader, wherein the bottom heat spreader and the top heat spreader are disposed on opposite sides of the semiconductor die, wherein an area of the top heat spreader is greater than an area of the semiconductor die, wherein the top heat spreader extends beyond the semiconductor die, wherein an area of the bottom heat spreader is greater than the area of the semiconductor die, wherein the bottom heat spreader extends beyond the semiconductor die, and wherein a total thickness of the top heat spreader and the bottom heat spreader is at least four times a thickness of the semiconductor die.

### CROSS-REFERENCE TO RELATED APPLICATION

This application claims the benefit of U.S. Provisional Patent Application No. 63/366,451, titled “SEMICONDUCTOR DEVICE PACKAGE WITH DUAL-SIDED COOLING,” filed Jun. 15, 2022, the entire contents of which is incorporated by reference herein and forms a part of this specification for all purposes as if fully set forth herein.

### BACKGROUND

### Technical Field

This application relates to semiconductor device packages. In particular, some embodiments relate to cooling integrated circuits and methods for manufacturing integrated circuit assemblies.

### Description of Related Technology

Semiconductor devices are used in a wide variety of applications. In some applications, semiconductor devices can experience high electrical loads that can result in significant heating of the semiconductor device. There are many problems associated with high electrical loads, such as detrimental heating of the semiconductor device. Current cooling solutions can be inadequate for certain applications. Thus, there is a need for improved cooling of semiconductor devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In some aspects, the techniques described herein relate to a device with dual sided surge power heat dissipation, including: a semiconductor die; a bottom heat spreader; and a top heat spreader, wherein the bottom heat spreader and the top heat spreader are disposed on opposite sides of the semiconductor die, wherein an area of the top heat spreader is greater than an area of the semiconductor die, wherein the top heat spreader extends beyond the semiconductor die, wherein an area of the bottom heat spreader is greater than the area of the semiconductor die, wherein the bottom heat spreader extends beyond the semiconductor die, and wherein a total thickness of the top heat spreader and the bottom heat spreader is at least four times a thickness of the semiconductor die.

In some aspects, the techniques described herein relate to a device, wherein the bottom heat spreader has at least one electrical contact and the top heat spreader has at least one electrical contact.

In some aspects, the techniques described herein relate to a device, further including a clip, wherein the clip is disposed on a same side of the semiconductor die as the top heat spreader and is configured to be in electrical and thermal contact with the semiconductor die, and wherein the clip is positioned between the semiconductor die and the top heat spreader.

In some aspects, the techniques described herein relate to a device, wherein the clip includes folded or shaped sheet metal.

In some aspects, the techniques described herein relate to a device, further including a thermistor or other passive die disposed on the clip.

In some aspects, the techniques described herein relate to a device, wherein the bottom heat spreader and the top heat spreader are both soldered to the semiconductor die.

In some aspects, the techniques described herein relate to a device, wherein the top heat spreader includes a lead frame.

In some aspects, the techniques described herein relate to a device, wherein at least one of the top and bottom heat spreaders include copper.

In some aspects, the techniques described herein relate to a device, wherein at least one of the top and bottom heat spreaders include metals.

In some aspects, the techniques described herein relate to a device, wherein the top and bottom heat spreaders both include copper or other metals.

In some aspects, the techniques described herein relate to a device, wherein the semiconductor die is positioned between the top and bottom heat spreaders so as to have a substantially neutral position for symmetric thermal expansion.

In some aspects, the techniques described herein relate to a device, wherein a thickness of the top heat spreader is greater than 1 mm and a thickness of the bottom heat spreader is greater than 1 mm.

In some aspects, the techniques described herein relate to a device, wherein a thickness of the top heat spreader is greater than 2 mm and a thickness of the bottom heat spreader is greater than 2 mm.

In some aspects, the techniques described herein relate to a device, wherein a thickness of the top heat spreader is greater than 3 mm and a thickness of the bottom heat spreader is greater than 3 mm.

In some aspects, the techniques described herein relate to a device with dual sided surge power heat dissipation, including: a semiconductor die; a bottom heat spreader; and a top heat spreader, wherein the bottom heat spreader and the top heat spreader are disposed on opposite sides of the semiconductor die, and wherein the bottom heat spreader and the bottom heat spreader together have sufficient thermal to maintain the semiconductor die at a temperature of less than 180 degrees Celsius when subjected to a surge load of up to 100 W for up to 0.5 seconds.

In some aspects, the techniques described herein relate to a device, wherein the bottom heat spreader has at least one electrical contact and the top heat spreader has at least one electrical contact.

In some aspects, the techniques described herein relate to a device, further including a clip, wherein the clip is disposed on a same side of the semiconductor die as the top heat spreader and is configured to be in electrical and thermal contact with the semiconductor die, and wherein the clip is positioned between the semiconductor die and the top heat spreader.

In some aspects, the techniques described herein relate to a device, wherein the clip includes folded or shaped sheet metal.

In some aspects, the techniques described herein relate to a device, further including a thermistor or other passive die disposed on the clip.

In some aspects, the techniques described herein relate to a device, wherein the bottom heat spreader and the top heat spreader are both soldered to the semiconductor die.

In some aspects, the techniques described herein relate to a device, wherein the top heat spreader includes a lead frame.

In some aspects, the techniques described herein relate to a device, wherein at least one of the top and bottom heat spreaders include copper.

In some aspects, the techniques described herein relate to a device, wherein at least one of the top and bottom heat spreaders include metals.

In some aspects, the techniques described herein relate to a device, wherein the top and bottom heat spreaders both include copper or other metals.

In some aspects, the techniques described herein relate to a device, wherein the semiconductor die is positioned between the top and bottom heat spreaders so as to have a substantially neutral position for symmetric thermal expansion.

In some aspects, the techniques described herein relate to a device, wherein a thickness of the top heat spreader is greater than 1 mm and a thickness of the bottom heat spreader is greater than 1 mm.

In some aspects, the techniques described herein relate to a device, wherein a thickness of the top heat spreader is greater than 2 mm and a thickness of the bottom heat spreader is greater than 2 mm.

In some aspects, the techniques described herein relate to a device, wherein a thickness of the top heat spreader is greater than 3 mm and a thickness of the bottom heat spreader is greater than 3 mm.

In some aspects, the techniques described herein relate to a semiconductor device assembly including: a packaged semiconductor device including: a semiconductor die; a bottom heat spreader; and a top heat spreader, wherein the bottom heat spreader and the top heat spreader are disposed on opposite sides of the integrated semiconductor die, wherein an area of the top heat spreader is greater than an area of the semiconductor die, wherein the top heat spreader extends beyond the semiconductor die, wherein an area of the bottom heat spreader is greater than the area of the semiconductor die, wherein the bottom heat spreader extends beyond the semiconductor die, and wherein a total thickness of the top heat spreader and the bottom heat spreader is at least four times greater than a thickness of the semiconductor die; a printed circuit board, the top heat spreader positioned between the printed circuit board and the packaged semiconductor die; and a cooling solution in thermal contact with the bottom heat spreader.

In some aspects, the techniques described herein relate to a semiconductor device assembly, wherein the bottom heat spreader is configured to electrically and thermally connect to at least one contact pad of a printed circuit board, and wherein the top heat spreader is configured to be in thermal communication with a heat sink.

In some aspects, the techniques described herein relate to a device, wherein the top heat spreader is electrically and thermally connected to a different contact pad of the printed circuit board than the at least one contact pad.

In some aspects, the techniques described herein relate to a semiconductor device assembly, wherein the semiconductor die is a power switching die.

In some aspects, the techniques described herein relate to a semiconductor device assembly, wherein the cooling solution includes a heatsink.

In some aspects, the techniques described herein relate to a semiconductor device assembly, wherein a thickness of the top heat spreader is greater than 1 mm and a thickness of the bottom heat spreader is greater than 1 mm.

In some aspects, the techniques described herein relate to a method of manufacturing any of the embodiments described herein.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

These and other features, aspects, and advantages of the disclosure are described with reference to the drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a plot of die temperature vs. time under steady state and surge load conditions.

FIG. 1B illustrates a heat map of temperature under surge load conditions.

FIGS. 2A-2C illustrate example dual-sided cooling packages according to embodiments herein.

FIG. 3 is an example illustration of heat flow from a die to dual heat spreaders according to embodiments herein.

FIG. 4 illustrates an exploded view of semiconductor device packages according to embodiments herein.

FIG. 5 illustrates an example semiconductor device package according to embodiments herein.

FIG. 6 illustrates another example semiconductor device package according to embodiments herein.

FIG. 7 illustrates an example semiconductor device package according to embodiments herein.

FIG. 8 illustrates an example of heat transfer paths according to embodiments herein.

FIG. 9 illustrates example precursor components and finished components according to embodiments herein.

FIG. 10 illustrates frame-mounted components according to embodiments herein.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. The headings provided herein are for convenience only and do not necessarily affect the scope or meaning of the claims.

### Introduction

Electronic components containing one or more integrated circuit (IC) dies may be deployed in a wide variety of applications. For example, such components may form part of a power electronics system. In some cases, such power electronics systems may be used for providing power for an electric vehicle or as part of a stationary energy storage system, such as a system for storing solar energy. There are many other applications for such systems. In some cases, components may comprise diode switches, field effect transistors (FETs) such as metal-oxide-semiconductor field effect transistors (MOSFETs) (e.g., GaN MOSFETs), insulated-gate bipolar transistors (IGBTs), other bipolar transistors, the like, or any suitable combination thereof. Any of these components can be implemented on any of the die of semiconductor device packages disclosed herein. In certain applications, such switches can be included in an inverter that converts a direct current (DC) voltage to an alternating current (AC) voltage or a rectifier that converts AC to DC. These components may have significant heat output when operational. In certain embodiments, electronic components can be provided in the form of packaged semiconductor devices.

Power electronics systems may produce significant amounts of heat both under steady state load conditions and under surge conditions. Such heat can present significant problems. For example, excess heat can lead to one or more of component damage, reduced lifetime, lower reliability, decreased performance, or the like. For example, excessive thermal stresses may weaken solder joints and/or damage semiconductor components. In some applications, surge loads may result in rapid temperature rises. High surge loads may be encountered in various applications, for example, when starting portable compressors, heating, ventilation, and air conditioning (HVAC) systems, refrigeration systems, electric motors, power converters, or the like.

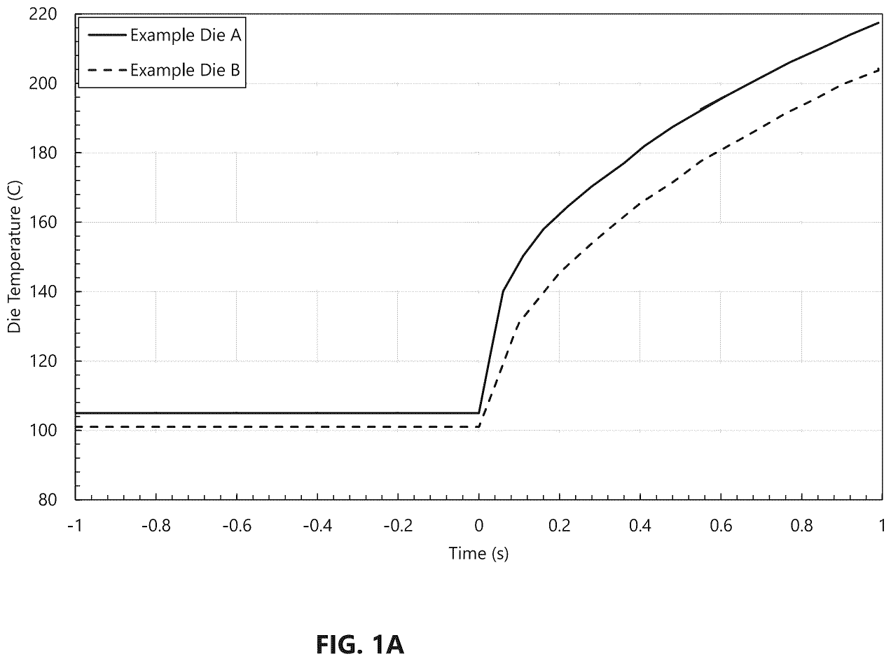

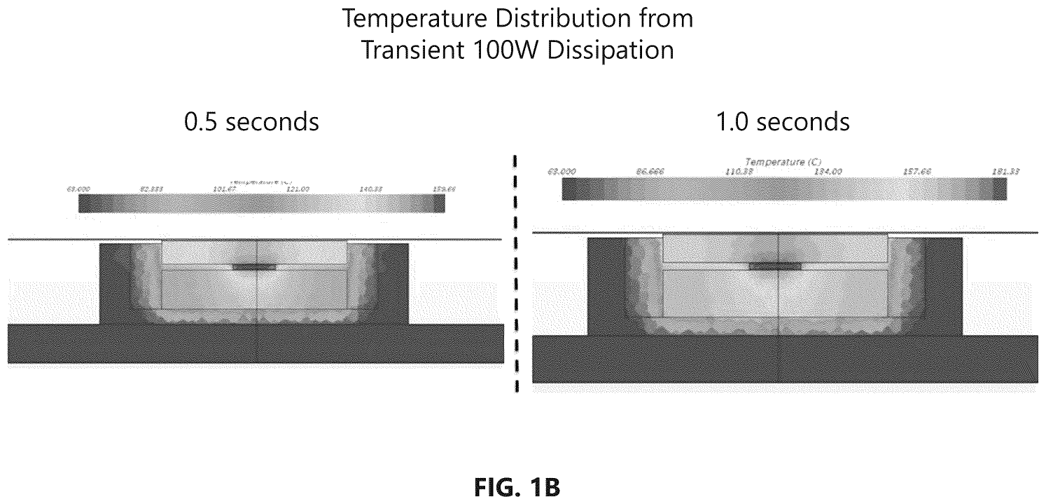

Even short surge loads of about one half to one second can cause significant changes in temperature. Conventional cooling solutions may struggle to handle rapid rises in heat generation. For example, as shown in FIG. 1A, a die operating in a steady state and consuming 18 W of power can operate at a temperature of about 100° C. when using conventional cooling through the printed circuit board (PCB). When a surge load of 100 W is applied for one half second, the die temperature can rise by about 50° C. or more. After one second, the die temperature can rise to about 220° C. or more, depending on the particular cooling solution. FIG. 1A includes die temperature over time curves for two die having different surface areas, where the example die B has a greater surface area than example die A. In some cases, dies can be attached directly to a lead frame or die paddle (which can operate as a heat spreader within a molded semiconductor device package). The semiconductor device package may be affixed with heatsinks, cold plates, or the like to aid in dissipating heat. However, adding mass to a heatsink (e.g., by adding a pedestal on top of the heat sink or otherwise increasing the mass of the heatsink) and/or adding external heat spreaders may not significantly help to manage die temperatures during surge conditions. The semiconductor device package may lack good thermal contact with the added mass and thus may be unable to take advantage of the added thermal capacity in a short period of time. For example, heat may travel through a thermal interface material (e.g., thermal paste, thermal pad, solder, etc.) before reaching the heatsink, which may limit the rate of heat transfer, which can play a significant role in managing die temperatures during surge loads. FIG. 1B shows example simulations of temperature gradients of a die package after different periods of time under a transient load.

In many cases, electronic components may be designed to operate under steady state conditions. For example, heat transfer materials inside a component may be sized to handle heat from common load conditions. Such an approach can offer many advantages, such as minimizing size and reducing cost as less material may be used. However, such approaches may not be suitable for certain types of use cases, such as handling large and/or surge loads.

Semiconductor device packages may be cooled from one side, such as bottom cooled through a PCB. However, heat conduction through the PCB may be inadequate for certain applications. In some cases, a “coin” comprising copper or another thermally conductive material may be embedded within the PCB under an electronic component to facilitate cooling. However, such an approach can add additional cost and complexity to the PCB and may reduce the density of components on the PCB. Moreover, power electronics systems can raise the temperature of the PCB assembly to temperatures in excess of 100° C., which can limit the flow of heat away from a semiconductor device package via the PCB. Alternatively, in some cases a PCB may be configured with holes that expose the bottom side of the semiconductor device package and a heat sink or other thermal transfer apparatus may be in thermal contact with the bottom side of the semiconductor device package through the hole. In some cases, top-sided cooling may be used to cool semiconductor device packages, for example as described in U.S. Pat. No. 10,658,276, entitled “Device with top-side base plate,” the contents of which are incorporated by reference for all purposes as if fully set forth herein.

In some cases, a cooling solution may be designed to handle both large, sustained loads and short surge loads. Thus, the cooling solution may be designed with not only large thermal capacity but also with rapid heat transport capabilities. This disclosure describes examples of systems and techniques for providing efficient cooling solutions that do not further complicate PCB design or component installation processes. Preferably, such a cooling solution may be manufactured using established, efficient manufacturing methods.

### Dual-Sided Cooling Packages

In some embodiments, heat spreaders may be in thermal contact with both sides of a die and may function as thermal reservoirs for direct, concurrent heat dissipation above and below the die. In some embodiments, a top heat spreader and a bottom heat spreader can be in contact and/or thermal communication with a semiconductor die. To facilitate heat dissipation, the top heat spreader and the bottom heat spreader can each be thicker than the semiconductor die. A total thickness of the top heat spreader and the bottom heat spreader can be at least 4 times a thickness of the semiconductor die. This can facilitate dissipation of a power surge from steady state. A total thickness of the top heat spreader and the bottom heat spreader can be in a range from 4 times a thickness of the semiconductor die to 10 times a thickness of the semiconductor die. In some embodiments, the top heater spreader and the bottom heat spreader can together have a thermal mass sufficient to maintain a die at a temperature of less than 170° C., less than 160° C., or less than 150° C. when the die is subjected to a surge load of up to 100 W or up to 160 W from steady state for 0.5 seconds. In some embodiments, the top heater spreader and the bottom heat spreader can together have a thermal mass sufficient to maintain a die at a temperature of less than 200° C., less than 190° C., or less than about 180° C. when the die is subjected to a surge load of up to 100 W or up to 160 W from steady state for 1 second. The top heat spreader and the bottom heat spreader can each have an area that is greater than the area of the die. The top heat spreader and the bottom heat spreader can each extend beyond the die.

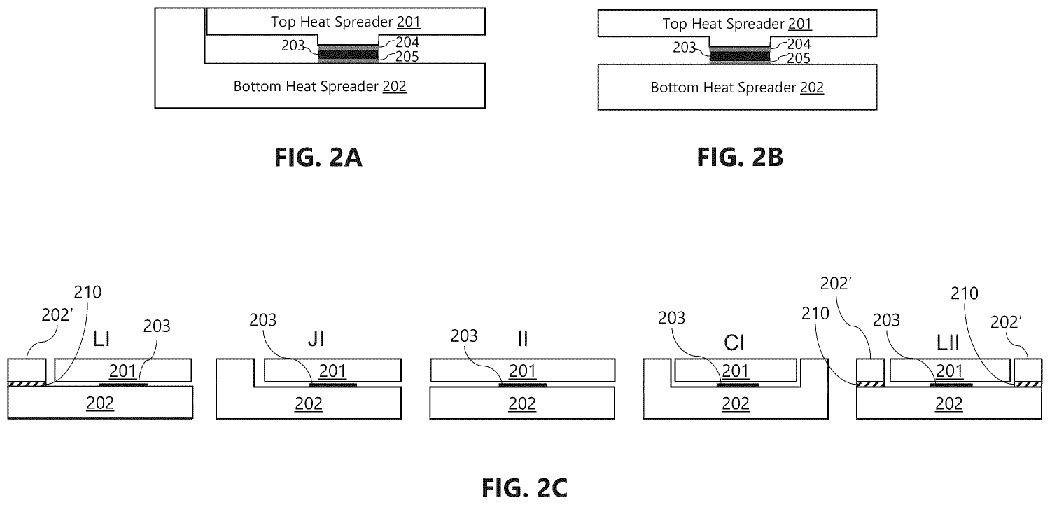

FIGS. 2A and 2B illustrate example embodiments of dual heat spreader systems. As shown in FIGS. 2A and 2B, a top heat spreader 201 and a bottom heat spreader 202 may be in thermal contact with a die 203 via solder 204 and 205. The die 203 can be an IC die. The die 203 can be a semiconductor switching die. In some embodiments, sintering or epoxy bonding may be used instead of the solder 204 and 205. In some embodiments, the dual heat spreaders (e.g., plates) may be nested, for example, as shown in FIG. 2A. In some other embodiments, the dual heat spreaders may be stacked on top of one another, for example, as depicted in FIG. 2B.

The top heat spreader 201 can comprise copper. For example, the top heat spreader 201 can be mostly or entirely copper. The bottom heat spreader 202 can comprise copper. For example, the bottom heat spreader 202 can be mostly or entirely copper. The top heat spreader 201 and the bottom heat spreader 202 can be sufficiently thick to concurrently dissipate heat associated with a power surge. Such thicknesses can be significantly greater than conventional thicknesses sufficient to achieve steady state heat dissipation for a stable maximum die temperature. The top heat spreader 201 and the bottom heat spreader 202 can dampen an increase in temperature of the die 203 in the presence of a momentary power surge. Accordingly, a dual heat spreader system can keep the die and package within power surge specifications.

The die 203 can be positioned between the top heat spreader 201 and the bottom heat spreader 202 so as to have a substantially neutral position for symmetric thermal expansion. This can reduce or eliminate coefficient of thermal expansion (CTE) mismatch stresses.

FIG. 2C illustrates various example embodiments of dual heat spreaders. In some embodiments, there may be only two components (e.g., a top heat spreader 201 and a bottom heat spreader 202), while in other embodiments there can be more than two components, and some of the components can be joined using an electrically conductive joining material 210 such as solder, sintering paste, or epoxy. For example, the “LI” and “LII” example embodiments shown in FIG. 2C can have one or more pieces 202′ attached to and in electrical communication with a bottom heat spreader portion. In some embodiments, the heat spreader components may be joined by other methods such as, for example, ultrasonic welding, laser welding, diffusion bonding, impact welding, friction welding, or riveting.

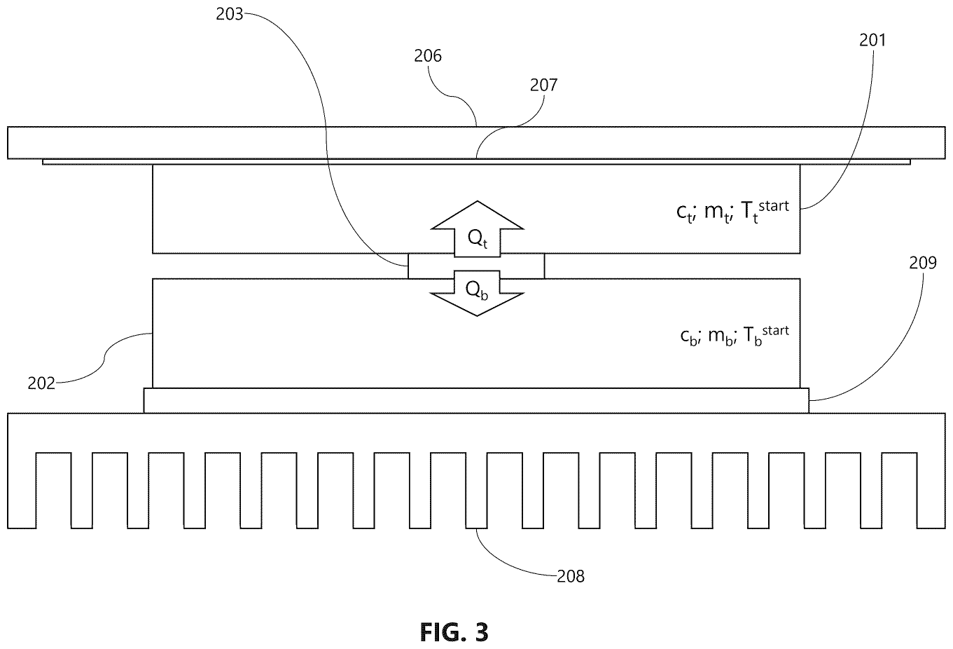

FIG. 3 is an example illustration of heat flow from a die to dual heat spreaders according to some embodiments. As shown in FIG. 3, a die 203 can be disposed between a top heat spreader 201 and a bottom heat spreader 202. The top heat spreader 201 can be in thermal and/or electrical contact with a PCB 206 via an interface material 207. The interface material can be, for example, a metal such as a copper contact pad. In some embodiments, the interface material 207 may not be present. In some embodiments, the PCB 206 can be any other suitable substrate for mounting a packaged electronic device. The bottom heat spreader 202 can be in thermal communication with a cooling solution 208 via a thermal interface material 209 and/or other gap filler material. In some embodiments, the cooling solution 208 can be a heatsink. In some embodiments, the cooling solution 208 can include fins. In some embodiments, the cooling solution 208 can be a cold plate or another suitable cooling solution.

In some embodiments, the thicknesses of the top heat spreader and the bottom heat spreader can be enhanced or optimized using the equation Q=mcΔT, where Q is the absorbed energy, m is mass, c is specific heat capacity, and ΔT is a change in temperature. Thus, for example, for a dual heat spreader arrangement, the total absorbed heat can be given by Q=mᵢcᵢΔTᵢ+m_{b}c_{b}Δ_{Tb}. As used herein, the subscript t denotes the top heat spreader and the subscript b denotes the bottom heat spreader. If the top and bottom heat spreaders are made of the same material, the equation can be simplified as cₜ and c_{b} are the same. In some embodiments, masses, mass proportions (e.g., the mass of the top heat spreader relative to the bottom heat spreader) can be enhanced or optimized by considering, at least in part, initial and target maximum temperatures to achieve a particular total energy absorption. In some embodiments, geometric and/or spatial optimizations can be performed using simulations, for example 3D transient thermal simulations.

As used herein, top and bottom are used to indicate that the heat spreaders are principally on opposite sides of a die. In some embodiments, the “top” side may be the side closest to the PCB, but in some embodiments the top side may face away from the PCB. The top heater spreader can also be referred to as a lead frame or PCB lead frame. The bottom heat spreader can also be referred to as die paddle.

In some embodiments, a bottom heat spreader (e.g., bottom plate) may face outward away from the PCB and may be designed to interface with a cold plate or heatsink which may be cooler than the PCB. In some embodiments, the bottom heat spreader may be the primary thermal reservoir at lower temperatures, for example, during steady state operation. Thus, the bottom heat spreader may be proportionally more massive than the top heat spreader (e.g., top plate), which may be designed primarily for addressing rapid thermal demands due to surge loads. The proportion of the top heat spreader compared with the bottom heat spreader may be tuned to absorb transient heat loads to enable higher overall energy absorption within defined parameter limits (for example, a maximum die temperature limit that can be sustained for a defined period of time). The bottom heat spreader and top heat spreader may additionally or alternatively be proportioned or otherwise designed to reduce temperature gradients in the vicinity of the die during high load events.

As mentioned above, the top heat spreader may be arranged to address rapid heat absorption when momentary surge loads are applied to the die, resulting in the generation of heat in excess of steady-state operation. The top heat spreader may be soldered or sintered to the die and can be substantially thicker than is commonly used for facilitating electrical conduction with the PCB. For example, the top and bottom heat spreaders may be about 1 mm, 2 mm, about 3 mm, about 4 mm, or about 5 mm thick, or any thickness between these numbers, or even more if desired.

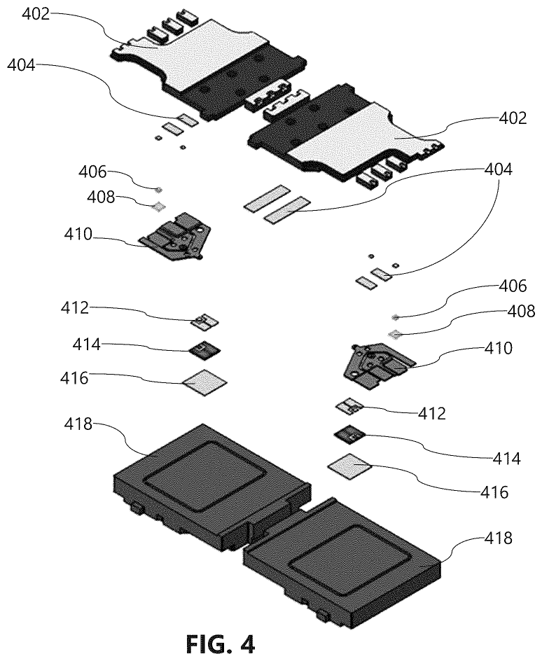

FIG. 4 depicts an exploded view of two semiconductor device packages with dual-sided cooling according to some embodiments. As explained in more detail below, in some embodiments, semiconductor device packages can be manufactured in a facing configuration as depicted in FIG. 4, although it will be appreciated that such a manufacturing process is not necessary. A semiconductor device package can include a PCB lead frame 402 (also referred to as a lead frame), solder 404, thermistor 406, solder 408, die clip 410, solder 412, die 414, solder 416, and die paddle 418. As shown in FIG. 4, solder 416 is used to attach a die 414 to a die paddle 418, which may be, for example, a copper block, an AlN block, or other material having desirable electrical and thermal conduction properties. The die paddle 418 can be a bottom heat spreader. A die clip 410 may be attached to the opposite side of the die 414 than the die paddle 418 using solder 412. The die clip 410 can be low profile. The die clip 410 can reduce drain and source loop inductance and associated losses. A lead frame 402 may be soldered to the die clip 410 using solder 404. The lead frame 402 can be a top heat spreader. In some embodiments, the semiconductor device package may include other active or passive die(s). For example, a passive die 406 may be a thermistor attached to the die clip 410 using solder 408.

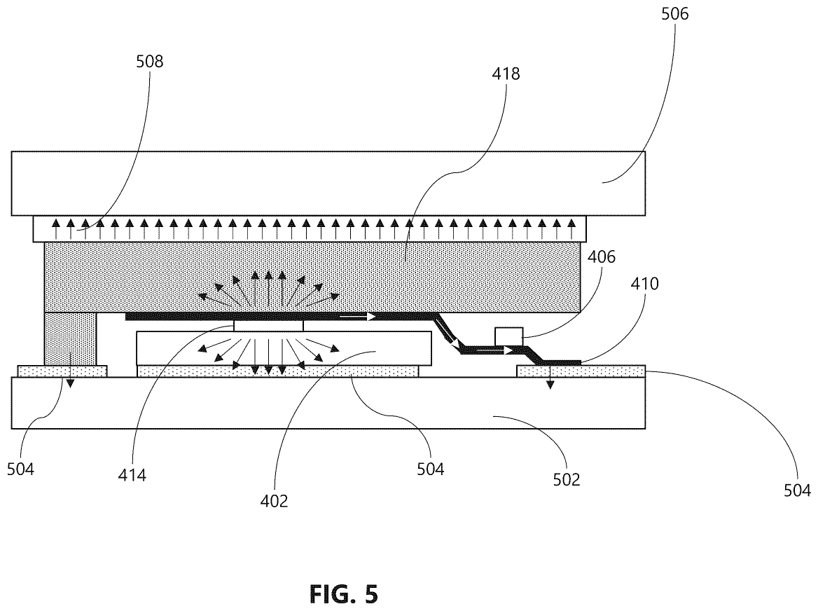

FIG. 5 shows a side view of a semiconductor device package with dual-sided cooling according to some embodiments. The semiconductor device package can include a lead frame 402, a passive die 406, die clip 410, die 414, and die paddle 418. The illustrated components can be affixed to one another by solder, for example as shown in FIG. 4. For simplicity, solder is omitted from FIG. 5. The semiconductor device package can include a heatspreader 506 in thermal contact with the die paddle 418 via a thermal interface material 508. The heatspreader can be a cold plate, heatsink, or any other suitable cooling solution. The semiconductor device package may be disposed on a PCB 502 having copper contact pads 504 disposed therein. The die paddle 418 can operate as a drain contact for the die 414 and can be affixed to a contact pad 504 (e.g., a copper contact pad) and the die 414 may be disposed thereon, for example, by soldering as shown in FIG. 4. A die clip 410 may be used to provide a source contact for the semiconductor device and may be in electrical and thermal contact with a second copper pad 504 on the PCB 502 and the top of the die 414. The heat spreader 506 may be placed in thermal contact with the die clip 410. In some embodiments, a passive die 406 (e.g., a thermistor) may be disposed on the die clip 410 for monitoring a temperature of the semiconductor device. The thermal interface material 508 may be used to place the die paddle 418 in thermal contact with the heat spreader 506. In some embodiments, the heat spreader 506 can be outside the semiconductor device package. In some embodiments, the heat spreader 506 can be part of the semiconductor device package. For example, the heat spreader 506 can have an outward facing surface disposed at or near an outer surface of the semiconductor device package.

In FIG. 5, arrows are shown indicating paths through which heat can be transported away from a die. For example, heat can flow through the die clip 410, through the contact pad 504, and into the PCB 502. Heat can flow through the lead frame 402, to the contact pad 504, then to the PCB 502. Heat can flow through the die paddle 418 and the thermal interface material 508 to the heat spreader 506.

In the system of FIG. 5, the die 414 can be a high power die arranged for 1 kV or higher operation (e.g., 1200 V operation). The die can include power switches and/or other components.

Although a single die is illustrated between a die paddle and a heat spreader in FIG. 5, two or more dies can be included between the die paddle and heat spreader in some other applications. In such applications, the two or more dies can be in electrical and/or thermal communication with each other.

It will be appreciated that FIG. 5 is merely an example and other embodiments are possible. For example, in some embodiments, the die paddle and clip may not both be used to provide electrical contacts, or additional or alternative contacts may be provided. If contacts are provided, they may be designed to improve electrical properties. For example, source and drain connections may be tightly nested to reduce parasitic inductance. In some embodiments, a lead frame can implement the heat spreader.

Placing a die between two thermal transfer materials (e.g., a thermally massive die paddle and a thermally massive heat spreader or lead frame) presents several challenges. The metals used for electrical contacts and heat transfer may expand significantly when heated. For example, copper may expand by about 17 ppm/° C. in certain applications. Thermal expansion can result in stress on the die. Thus, in some embodiments, a die may be centered on the paddle and/or the heat spreader (or lead frame) in order to reduce or minimize non-uniformities in stresses that could result in damage to the die.

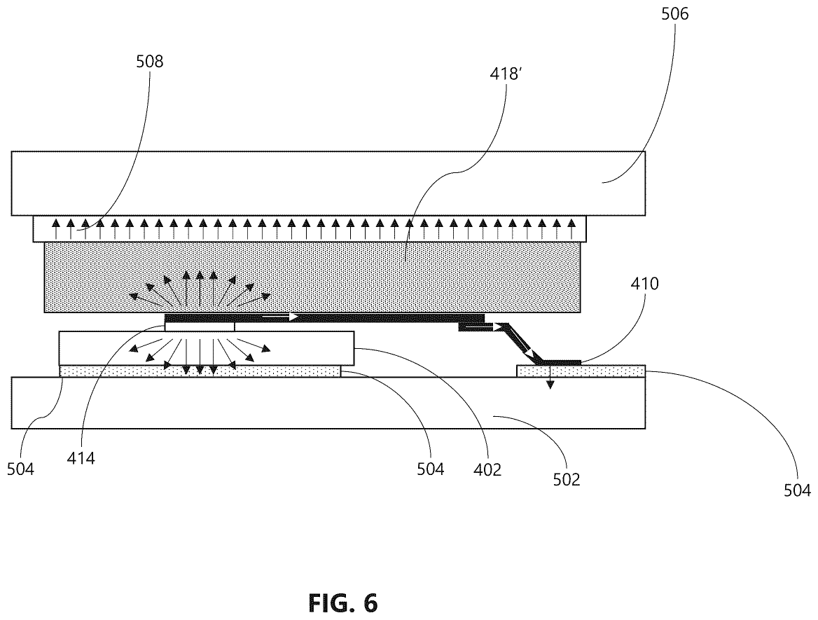

FIG. 6 illustrates another example embodiment of a semiconductor device package according to some embodiments herein. The embodiment of FIG. 6 is generally similar to that of FIG. 5. In FIG. 6, the bottom heat spreader 418′ (also referred to as a die paddle) can have a different structure than the bottom heat spreader of FIG. 5. For example, in FIG. 5, the die paddle 418 is directly electrically connected to a contact pad of the PCB. In FIG. 6, the bottom heat spreader 418′ is not directly electrically connected to a contact pad of the PCB. In FIG. 6, a die is placed on a thermally massive die paddle, and the top surface of the die is in contact with a clip. A heat spreader is in contact with the clip. As shown in FIG. 6, heat may flow from the die to the paddle and eventually to the PCB by way of a pad (e.g., a copper pad). Heat can also concurrently flow from the die to the clip, to the heat spreader, and eventually to the heatsink by crossing a thermal interface material, which may have a wide range of thermal conductivities. Further, some heat energy may travel along the clip and eventually to the PCB by way of a pad (e.g., a copper pad) that is in contact with the clip.

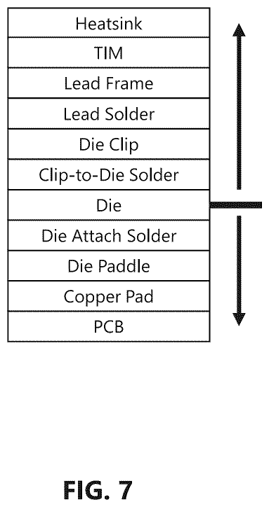

FIG. 7 illustrates heat transfer paths for semiconductor device assemblies according to some embodiments herein. As shown in FIG. 7, two primary pathways are provided for carrying heat away from the die. From the die to the PCB, heat may be transported from the die, through the die attach solder, to the die paddle, to a pad (e.g., a copper pad) that the device package is mounted on, and eventually into the PCB. Alternatively or additionally, heat may travel from the die through the clip-to-die solder, through the die clip, through the lead solder, and into the lead frame. Heat may be carried away from the lead frame and out of the device package to the heatsink via a thermal interface material.

An arrangement as depicted in FIG. 7 allows heat to be carried away from the die in two directions with relatively high efficiency. Advantageously, large thermal masses are in contact with the die without the use of a thermal interface material (e.g., a thermal paste or pad), as thermal interface material can be a thermal bottleneck. Thermal interface materials typically have high thermal impedance compared to metals. Die attachment joining compounds such as solders, sintering pastes, and epoxies may offer significantly higher thermal conductivity and lower interface impedance than typical thermal interface materials. For example, solder may have a thermal conductivity of at least about 20 W/m·K, 50 W/m·K, or 80 W/m K or more, depending on the solder. Typical dielectric, electrically insulative thermal interface materials may have a thermal conductivity of less than about 10 W/m·K, although some specialized materials may achieve somewhat higher thermal conductivities.

While FIGS. 4-7 depict the die clip as a separate component from the heat spreader, the die clip and the heat spreader can be a single integrated component in certain embodiments. In some embodiments, the heat spreader and die clip may be separate components. In some embodiments, the heat spreader and clip may be pre-joined. In some embodiments, the die clip may be a sheet metal clip and may be folded such that it acts as a double-thickness stepped area for die connections and as a heat spreader. As discussed above, in some embodiments, the die clip may have a thermistor secured thereto, for example by soldering. In some embodiments, pre-joining the die clip and heat spreader or forming the die clip and heat spreader as a single component can simplify a manufacturing process for packaged semiconductor device, for example by reducing a number of reflow steps in the manufacturing process.

In some embodiments, contact pads and/or other features on the PCB may be shaped, sized, and arranged to facilitate heat transfer and power conduction laterally on heat-conductive PCB planes and may utilize heat-spreading effects to carry heat away from a device package. In some embodiments, the PCB may comprise thermal vias which can be used to transport heat to underlying PCB planes.

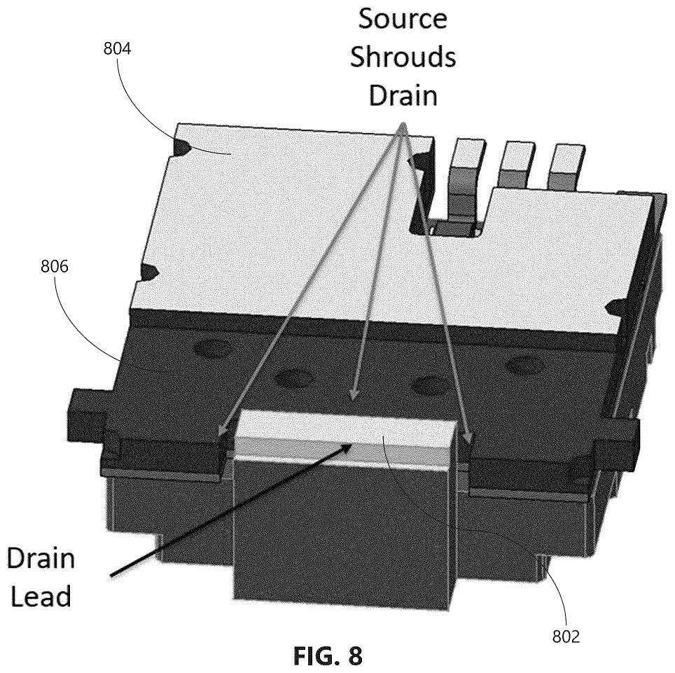

In some embodiments, the contacts on the exterior of the semiconductor device package may be positioned to reduce or minimize surface creepage. For example, in some high power applications, a device may have a source and drain potential drop of about 1 kV or more, which can lead to substantial surface creepage distances. Thus, the source lead 804 and drain lead 802 may be kept a significant distance apart, for example about 4 mm, 5 mm, or 6 mm, or more, as depicted in FIG. 8. In some embodiments, contacts may be kept as far apart as possible without increasing the size of the package beyond acceptable limits. In some embodiments, surface mount device (SMD) epoxy grooves 806 may be used to direct a flow path for forming curvilinear epoxy patterns to provide an underside high voltage isolation between features of a component assembly and the PCB.

### Dual-Sided Heat Spreader Design and Manufacturing

Preferably, a semiconductor package with dual-sided cooling can be manufactured using conventional techniques in order to minimize cost and/or improve yield. Thus, for example, while heat spreaders of substantial thickness may be desirable for cooling, the thickness of heat spreaders may be limited, for example to about 3 mm or less so that the metal components such as the lead frame of the semiconductor package can be manufactured using reel to reel manufacturing processes.

In some embodiments, each of the dual heat spreaders may be produced from a single profiled copper strip using stamp forming, angular bending, cutting, and/or other manufacturing techniques. In some embodiments, dual heat spreaders may be affixed to thin stamped frames to improve manufacturing efficiency and to enable other shaping processes such as cold or hot forging and can optionally allow reel-to-reel manufacturing optionally.

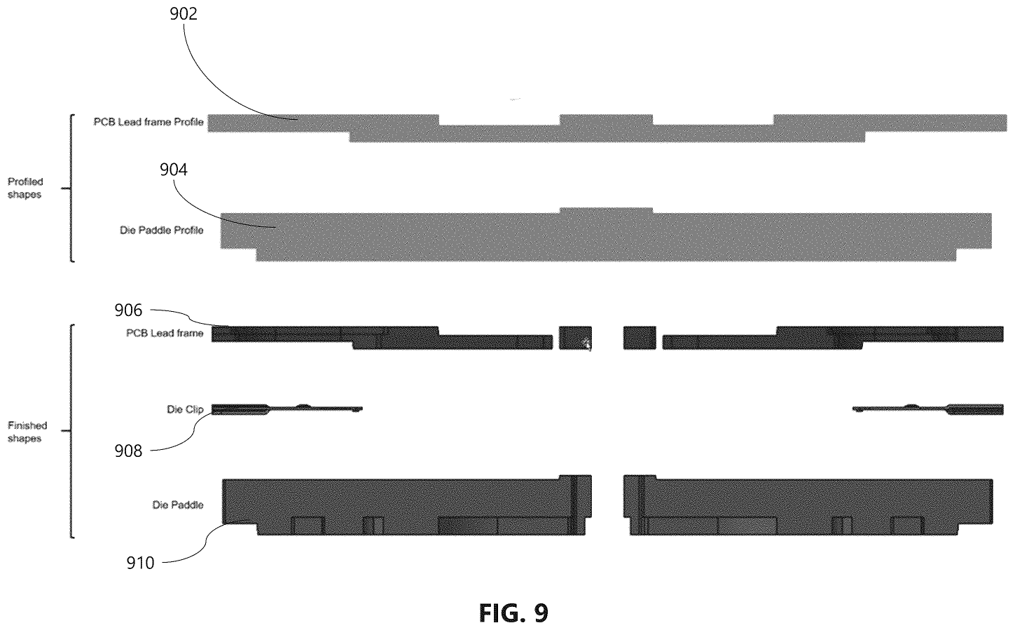

As shown in FIG. 9, profiled copper 902, 904 (or another suitable material) may be used to prepare a lead frame and a die paddle. For example, profiled copper 902 can have a lead frame profile and profiled copper 904 can have a die paddle profile. Typical manufacturing processes may be able to add grooves, recesses, and so forth as may be desirable for the finished shapes 906, 908, 910, without a need to remove large amounts of material, which can slow and/or complicate the manufacturing process. For example, finished shapes can include a lead frame 906, die clip 908, and/or die paddle 910.

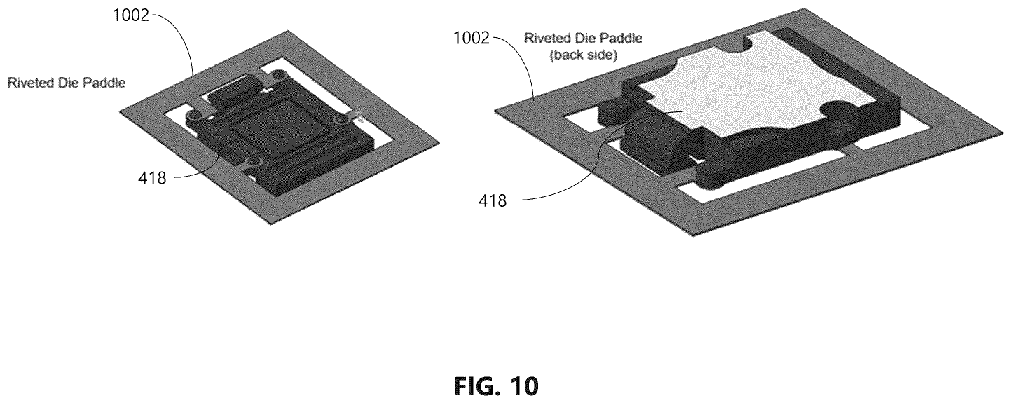

While the approach depicted in FIG. 9 has several advantages, there can still be manufacturing challenges. For example, after forming, there is still a need to cut, saw apart, dice, or otherwise singulate the shapes into individual components for manufacturing individual semiconductor die packages, and cutting through thick copper can significantly slow down the manufacturing process, among other drawbacks. Thus, in some embodiments the thick metal components may be hot forged and then mounted on a light, thin frame, as shown in FIG. 10. In FIG. 10, a die paddle 418 is riveted to a carrier frame 1002.

### Additional Embodiments

In the foregoing specification, the disclosure has been described with reference to specific embodiments. It will, however, be evident that various modifications and changes may be made thereto without departing from the broader spirit and scope of the disclosure. The specification and drawings are, accordingly, to be regarded in an illustrative rather than restrictive sense.

Indeed, although this disclosure is in the context of certain embodiments and examples, it will be understood by those skilled in the art that the inventions extend beyond the specifically disclosed embodiments to other alternative embodiments and/or uses of the inventions and equivalents thereof. In addition, while several variations of the embodiments have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments disclosed herein. Any methods disclosed herein need not be performed in the order recited. Thus, it is intended that the scope of the disclosure should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the disclosure is not to be limited to the particular forms or methods disclosed, but, to the contrary, the disclosure is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). Phrases preceded by a term such as “substantially” include the recited phrase and should be interpreted based on the circumstances (e.g., as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

Although the claims presented here are in single dependency format, it is to be understood that any claim may depend on any preceding claim of the same type except when that is clearly not technically feasible.

1. A device with dual sided surge power heat dissipation, comprising:
a semiconductor die;
a bottom heat spreader; and
a top heat spreader,
wherein the bottom heat spreader and the top heat spreader are disposed on opposite sides of the semiconductor die,
wherein an area of the top heat spreader is greater than an area of the semiconductor die, wherein the top heat spreader extends beyond the semiconductor die,
wherein an area of the bottom heat spreader is greater than the area of the semiconductor die, wherein the bottom heat spreader extends beyond the semiconductor die, and
wherein a total thickness of the top heat spreader and the bottom heat spreader is at least four times a thickness of the semiconductor die.

2. The device of claim 1, wherein the bottom heat spreader has at least one electrical contact and the top heat spreader has at least one electrical contact.

3. The device of claim 1, further comprising a clip, wherein the clip is disposed on a same side of the semiconductor die as the top heat spreader and is configured to be in electrical and thermal contact with the semiconductor die, and wherein the clip is positioned between the semiconductor die and the top heat spreader.

4. The device of claim 3, further comprising a thermistor or other passive die disposed on the clip.

5. (canceled)

6. The device of claim 1, wherein at least one of the top and bottom heat spreaders comprise copper.

7. The device of claim 1, wherein the semiconductor die is positioned between the top and bottom heat spreaders so as to have a substantially neutral position for symmetric thermal expansion.

8. (canceled)

9. The device of claim 1, wherein a thickness of the top heat spreader is greater than 3 mm and a thickness of the bottom heat spreader is greater than 3 mm.

10. The device of claim 1, wherein the top heat spreader and the bottom heat spreader are together configured to maintain the semiconductor die at a temperature of less than 160 degrees Celsius when subjected to a surge load of up to 100 W from a steady state for up to 0.5 seconds.

11. A device with dual sided surge power heat dissipation, comprising:
a semiconductor die;
a bottom heat spreader in thermal communication with the semiconductor die; and
a top heat spreader in thermal communication with the semiconductor die, wherein the bottom heat spreader and the top heat spreader are disposed on opposite sides of the semiconductor die, and
wherein the top heat spreader and the bottom heat spreader are together configured to maintain the semiconductor die at a temperature of less than 160 degrees Celsius when subjected to a surge load of up to 100 Watts from a steady state for up to 0.5 seconds.

12. The device of claim 11, wherein the top heat spreader and the bottom heat spreader are together configured to maintain the semiconductor die at a temperature of less than 200 degrees Celsius when subjected to a surge load of up to 100 Watts from a steady state for up to 1 second.

13. The device of claim 11, wherein the bottom heat spreader has at least one electrical contact and the top heat spreader has at least one electrical contact.

14. The device of claim 11, further comprising a clip, wherein the clip is disposed on a same side of the semiconductor die as the top heat spreader and is configured to be in electrical and thermal contact with the semiconductor die, and wherein the clip is positioned between the semiconductor die and the top heat spreader.

15. The device of claim 14, further comprising a thermistor or other passive die disposed on the clip.

16. (canceled)

17. (canceled)

18. The device of claim 11, wherein a thickness of the top heat spreader is greater than 2 mm and a thickness of the bottom heat spreader is greater than 2 mm.

19. A semiconductor device assembly comprising:
a packaged semiconductor device comprising:
a semiconductor die;
a bottom heat spreader; and
a top heat spreader,
wherein the bottom heat spreader and the top heat spreader are disposed on opposite sides of the semiconductor die,
wherein an area of the top heat spreader is greater than an area of the semiconductor die, wherein the top heat spreader extends beyond the semiconductor die,
wherein an area of the bottom heat spreader is greater than the area of the semiconductor die, wherein the bottom heat spreader extends beyond the semiconductor die, and
wherein a total thickness of the top heat spreader and the bottom heat spreader is at least four times a thickness of the semiconductor die;
a printed circuit board, the top heat spreader positioned between the printed circuit board and the packaged semiconductor die; and
a cooling solution in thermal contact with the bottom heat spreader.

20. The semiconductor device assembly of claim 19, wherein the bottom heat spreader is configured to electrically and thermally connect to at least one contact pad of a printed circuit board, and wherein the top heat spreader is configured to be in thermal communication with a heat sink.

21. The device of claim 20, wherein the top heat spreader is electrically and thermally connected to a different contact pad of the printed circuit board than the at least one contact pad.

22. The semiconductor device assembly of claim 19, wherein the cooling solution comprises a heatsink.

23. The semiconductor device assembly of claim 19, wherein a thickness of the top heat spreader is greater than 1 mm and a thickness of the bottom heat spreader is greater than 1 mm.

24. The semiconductor device assembly of claim 19, wherein the top heat spreader and the bottom heat spreader are together configured to maintain the semiconductor die at a temperature of less than 160 degrees Celsius when subjected to a surge load of up to 100 Watts from a steady state for up to 0.5 seconds.
